(19) United States
(12) Patent Application Publication
(10) Pub. No.: US 2025/0125312 A1
(43) Pub. Date: Apr. 17, 2025

(54) SEMICONDUCTOR PACKAGE INCLUDING PHOTONIC CHIP

(71) Applicant: SAMSUNG ELECTRONICS CO., LTD., Suwon-si (KR)

(72) Inventors: Junghoon Kang, Suwon-si (KR); Daegon Kim, Suwon-si (KR)

(21) Appl. No.: 18/773,021

(22) Filed: Jul. 15, 2024

(30) Foreign Application Priority Data
Oct. 11, 2023 (KR) 10-2023-0135402

(51) Int. Cl. H01L 25/065; G02B 6/42; G02B 6/43; H01L 23/00; H01L 23/13; H01L 23/48; H01L 23/498; H01L 23/538; H01L 27/144

(52) U.S. Cl. CPC H01L 25/0657; G02B 6/4245; G02B 6/43; H01L 23/13; H01L 23/5385; H10F 39/10; H01L 23/481; H01L 23/49816; H01L 24/32; H01L 24/33; H01L 25/0652; H01L 2224/32145; H01L 2224/32225; H01L 2224/33181; H01L 2225/06562

(57) ABSTRACT

A semiconductor package includes a package substrate, an electronic integrated circuit chip mounted on the package substrate, a first photonic integrated circuit chip mounted on the electronic integrated circuit chip, the first photonic integrated circuit chip including a first groove recessed from a top surface and a side surface of the first photonic integrated circuit chip, and a second photonic integrated circuit chip mounted on the first photonic integrated circuit chip, the second photonic integrated circuit chip including a second groove recessed from a top surface and a side surface of the second photonic integrated circuit chip, wherein the second photonic integrated circuit chip is offset-stacked on the first photonic integrated circuit chip, wherein at least a portion of a bottom surface of the first groove of the first photonic integrated circuit chip is exposed to the outside.

### CROSS-REFERENCE TO RELATED APPLICATION

This application claims priority under 35 U.S.C. § 119 to Korean Patent Application No. 10-2023-0135402, filed on Oct. 11, 2023, in the Korean Intellectual Property Office, the disclosure of which is incorporated by reference herein in its entirety.

### TECHNICAL FIELD

Aspects of this disclosure relate to semiconductor packages including photonic integrated circuit (PIC) chips, and to methods of manufacturing the semiconductor packages.

### BACKGROUND

Semiconductor packages are increasingly being utilized to increase the functionality of electronic devices and integrate the elements of electronic devices. Semiconductor packages may enable various integrated circuits, such as memory chips and logic chips, to be mounted on a package substrate. In a context in which data traffic has increased in data centers and communication infrastructure, there has been continuing research into semiconductor packages.

### SUMMARY

Some aspects of this disclosure provide a semiconductor package capable of decreasing an alignment error in the vertical direction.

Some aspects of this disclosure provide a semiconductor package having a plurality of photonic integrated circuit (PIC) chips stacked in the vertical direction.

According to some aspects of this disclosure, there is provided a semiconductor package including a package substrate, an electronic integrated circuit chip mounted on the package substrate, a first photonic integrated circuit chip mounted on the electronic integrated circuit chip, the first photonic integrated circuit chip including a first groove recessed from a top surface and a side surface of the first photonic integrated circuit chip, and a second photonic integrated circuit chip mounted on the first photonic integrated circuit chip, the second photonic integrated circuit chip including a second groove recessed from a top surface and a side surface of the second photonic integrated circuit chip, wherein the second photonic integrated circuit chip is offset-stacked on the first photonic integrated circuit chip, wherein at least a portion of a bottom surface of the first groove of the first photonic integrated circuit chip is exposed to the outside.

According to some aspects of this disclosure, there is provided a semiconductor package including a package substrate, an electronic integrated circuit chip mounted on the package substrate, a first photonic integrated circuit chip mounted on the electronic integrated circuit chip, the first photonic integrated circuit chip including a first groove recessed from a top surface and a side surface of the first photonic integrated circuit chip, a second photonic integrated circuit chip mounted on the first photonic integrated circuit chip, the second photonic integrated circuit chip including a second groove recessed from a top surface and a side surface of the second photonic integrated circuit chip, and an optical fiber unit including a frame, a first optical fiber, and a second optical fiber apart from the first optical fiber in a vertical direction, wherein the first optical fiber extends from the frame of the optical fiber unit and is located in the first groove of the first photonic integrated circuit chip, the second optical fiber extends from the frame of the optical fiber unit and is located in the second groove of the second photonic integrated circuit chip, and the second photonic integrated circuit chip is offset-stacked on the first photonic integrated circuit chip, wherein at least a portion of a bottom surface of the first groove of the first photonic integrated circuit chip is exposed to the outside.

According to some aspects of this disclosure, there is provided a semiconductor package including a main package substrate, a semiconductor chip mounted on a central portion of the main package substrate, a sub package substrate mounted on an edge portion of the main package substrate and apart from the semiconductor chip in a horizontal direction, an electronic integrated circuit chip mounted on the sub package substrate, a first photonic integrated circuit chip mounted on the electronic integrated circuit chip, the first photonic integrated circuit chip including a first photoelectric converter and a first groove recessed from a top surface and a first side surface of the first photonic integrated circuit chip, and a second photonic integrated circuit chip mounted on the first photonic integrated circuit chip, the second photonic integrated circuit chip including a second photoelectric converter and a second groove recessed from a top surface and a second side surfaces of the second photonic integrated circuit chip, wherein the first photoelectric converter includes an edge coupler at an end thereof adjacent to the first groove of the first photonic integrated circuit chip, the second photoelectric converter includes an edge coupler at an end thereof adjacent to the second groove of the second photonic integrated circuit chip, and the second photonic integrated circuit chip is offset-stacked on the first photonic integrated circuit chip, wherein an upper portion of at least a portion of the first groove of the first photonic integrated circuit chip is exposed to the outside.

### BRIEF DESCRIPTION OF THE DRAWINGS

Implementations will be more clearly understood from the following detailed description taken in conjunction with the accompanying drawings in which:

FIG. 1 is a schematic perspective view of a semiconductor package according to some implementations;

FIG. 2 is a schematic plan view of the semiconductor package of FIG. 1;

FIG. 3 is a schematic cross-sectional view of the semiconductor package of FIG. 2, taken along line A-A′ in FIG. 2;

FIG. 4 is an enlarged view of a region EX1 of the semiconductor package of FIG. 3;

FIG. 5 is an enlarged view of the region EX1 in FIG. 3 in a semiconductor package according to some implementations;

FIG. 6 is an enlarged view of the region EX1 in FIG. 3 in a semiconductor package according to some implementations;

FIG. 7 is an enlarged view of the region EX1 in FIG. 3 in a semiconductor package according to some implementations;

FIG. 8 is a schematic perspective view of a semiconductor package according to some implementations;

FIG. 9 is a schematic plan view of the semiconductor package of FIG. 8;

FIG. 10 is a schematic cross-sectional view of the semiconductor package of FIG. 9, taken along line B-B′ in FIG. 9;

FIG. 11 is a schematic perspective view of a semiconductor package according to some implementations;

FIG. 12 is a schematic plan view of the semiconductor package of FIG. 11;

FIG. 13 is a schematic cross-sectional view of the semiconductor package of FIG. 12, taken along line C-C′ in FIG. 12;

FIG. 14 is a schematic perspective view of a semiconductor package according to some implementations;

FIG. 15 is a schematic cross-sectional view of the semiconductor package of FIG. 14, taken along line D-D′ in FIG. 14; and

FIGS. 16 to 18 are diagrams of a method of manufacturing a semiconductor package, according to some implementations.

### DETAILED DESCRIPTION

As implementations allows for various changes and numerous examples, some examples will be illustrated in the drawings and described in detail in the written description. However, this is not intended to limit the scope of this disclosure to those particular examples.

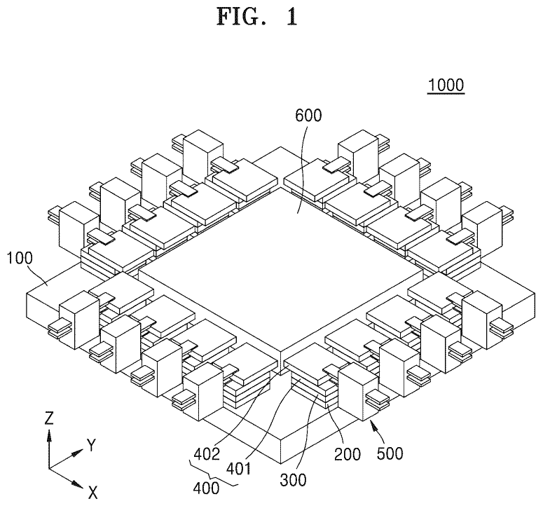

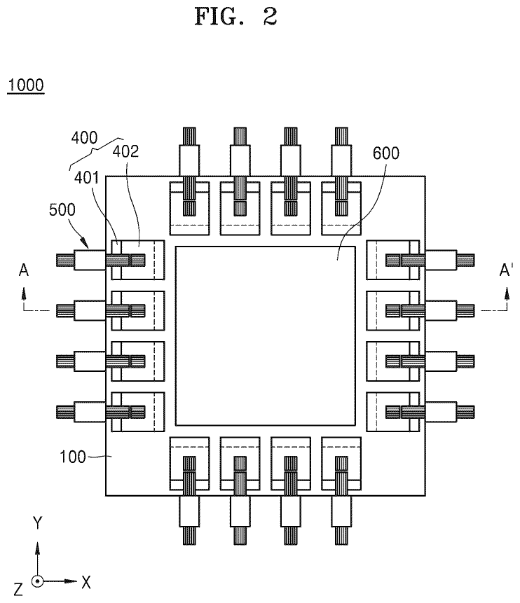

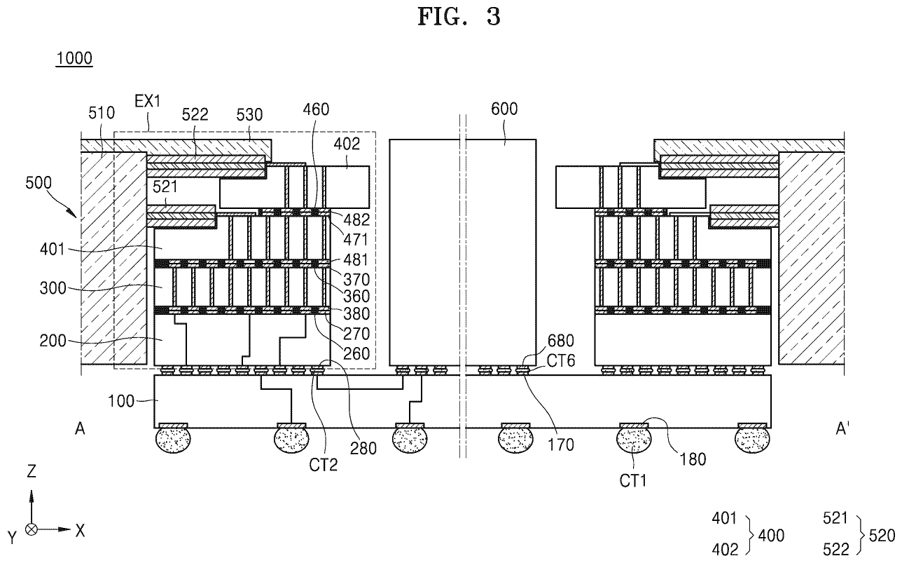

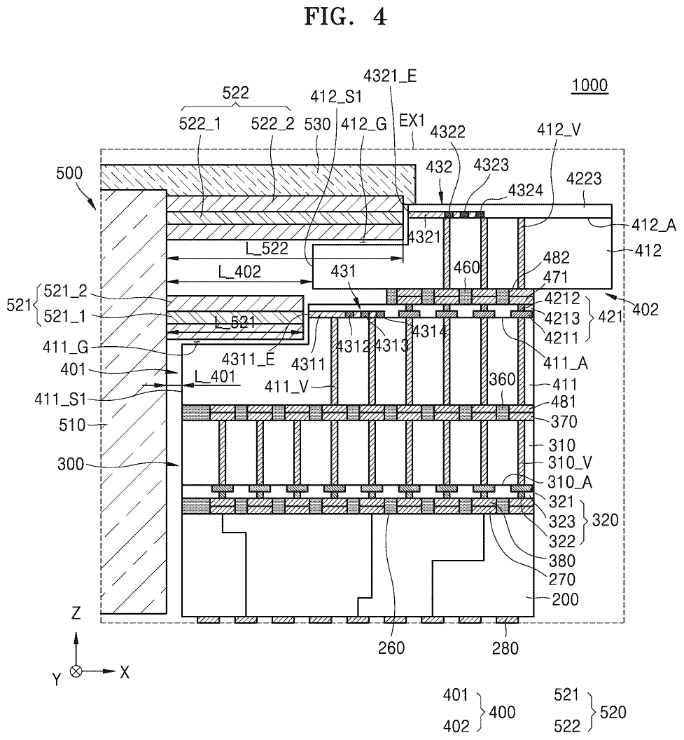

FIG. 1 is a schematic perspective view of a semiconductor package 1000 according to some implementations. FIG. 2 is a schematic plan view of the semiconductor package 1000 of FIG. 1. FIG. 3 is a schematic cross-sectional view of the semiconductor package 1000 of FIG. 2, taken along line A-A′ in FIG. 2. FIG. 4 is an example of an enlarged view of a region EX1 of the semiconductor package 1000 of FIG. 3.

Referring to FIGS. 1 to 4, the semiconductor package 1000 may include a main package substrate 100, a sub package substrate 200, an electronic integrated circuit (EIC) chip 300, and a plurality of photonic integrated circuit (PIC) chips 400. In some implementations, an optical fiber unit 500 including a plurality of optical fibers 520 may be mounted on each of the PIC chips 400.

Hereinafter, unless particularly defined, a direction parallel with the top surface of the main package substrate 100 is defined as a first horizontal direction (the X direction), a direction perpendicular to the top surface of the main package substrate 100 is defined as the vertical direction (the Z direction), and a direction perpendicular to the first horizontal direction (the X direction) and the vertical direction (the Z direction) is defined as a second horizontal direction (the Y direction). A “horizontal direction” can refer to either or both of the first horizontal direction (the X direction) and the second horizontal direction (the Y direction).

For example, each of the main package substrate 100 and the sub package substrate 200 of the semiconductor package 1000 may correspond to a printed circuit board (PCB). In some implementations, the sub package substrate 200 may be referred to as a package substrate.

The sub package substrate 200 may be arranged above the main package substrate 100. For example, a plurality of sub package substrates 200 may be mounted on one main package substrate 100. Although it is illustrated in FIG. 1 that four sub package substrates 200 are mounted on each of the edges of the top surface of the main package substrate 100, the number of sub package substrates 200 is not limited thereto.

Each of the main package substrate 100 and the sub package substrate 200 may include a core insulating layer including at least one material selected from the group consisting of phenol resin, epoxy resin, and polyimide. For example, the core insulating layer may include at least one material selected from the group consisting of polyimide, flame retardant 4 (FR4), tetrafunctional epoxy, polyphenylene ether, epoxy/polyphenylene oxide, bismaleimide triazine (BT), thermount, cyanate ester, and liquid crystal polymer.

The main package substrate 100 may include an upper pad 170 on the top surface of the core insulating layer thereof and a lower pad 180 at the bottom of the core insulating layer thereof. Each of the upper pad 170 and the lower pad 180 may correspond to a portion of a circuit wiring, which is formed by disposing a copper foil on the top and bottom surfaces of the core insulating layer of the main package substrate 100 and patterning the copper foil. For example, each of the upper pad 170 and the lower pad 180 may correspond to a region of the circuit wiring that is not covered by a solder resist layer and is thus exposed to the outside.

In some implementations, each of the upper pad 170 and the lower pad 180 may include copper, nickel, stainless steel, or beryllium copper. An internal wiring may be formed in the main package substrate 100 to electrically connect the upper pad 170 to the lower pad 180.

External connection terminals CT1 may be attached to the lower pad 180. The external connection terminals CT1 may be configured to electrically and physically connect the main package substrate 100 to an external device, on which the main package substrate 100 is mounted. For example, the external connection terminals CT1 may be formed from a solder ball or a solder bump.

The sub package substrate 200 may include an upper pad 270 on the top surface of the core insulating layer thereof and a lower pad 280 on the bottom surface of the core insulating layer thereof. Each of the upper pad 270 and the lower pad 280 may correspond to a portion of a circuit wiring, which is formed by disposing a copper foil on the top and bottom surfaces of the core insulating layer of the sub package substrate 200 and patterning the copper foil. For example, each of the upper pad 270 and the lower pad 280 may correspond to a region of the circuit wiring that is not covered with a solder resist layer and is thus exposed to the outside.

In some implementations, each of the upper pad 270 and the lower pad 280 may include copper, nickel, stainless steel, or beryllium copper. An internal wiring may be formed in the sub package substrate 200 to electrically connect the upper pad 270 to the lower pad 280.

External connection terminals CT2 may be attached to the lower pad 280 of the sub package substrate 200. The external connection terminals CT2 may be configured to electrically and physically connect the sub package substrate 200 to the main package substrate 100. For example, the external connection terminals CT2 may be formed from a solder ball or a solder bump. However, a method of electrically connecting the sub package substrate 200 to the main package substrate 100 is not limited to that described above.

In some implementations, the sub package substrate 200 may be mounted on the main package substrate 100 through a socket arranged on the main package substrate 100. For example, the socket may include at least one of a land grid array (LGA) and a pin grid array (PGA). The sub package substrate 200 may be easily attached to and detached from the main package substrate 100 through the socket.

A semiconductor chip 600 of the semiconductor package 1000 may be mounted on the main package substrate 100. The semiconductor chip 600 may be spaced apart from the sub package substrate 200 in the horizontal direction. For example, the semiconductor chip 600 may be located in a central portion of the main package substrate 100 and the sub package substrate 200 may be located in an edge portion of the main package substrate 100.

The semiconductor chip 600 may include an active surface and an inactive surface opposite to the active surface. In some implementations, the semiconductor chip 600 includes an application specific integrated circuit (ASIC).

In some implementations, the semiconductor chip 600 may be mounted on the main package substrate 100 such that the active surface of the semiconductor chip 600 faces downwards. In some implementations, a lower pad 680 of the semiconductor chip 600 may be electrically connected to the upper pad 170 of the main package substrate 100 through a connection terminal CT6. However, a method of connecting the semiconductor chip 600 to the main package substrate 100 is not limited to that described above.

In some implementations, various kinds of individual devices may be arranged on the active surface of the semiconductor chip 600. For example, individual devices may include various microelectronic devices, e.g., a complementary metal-oxide-semiconductor (CMOS) transistor, a metal-oxide-semiconductor field effect transistor (MOSFET), a system large scale integration (LSI), an image sensor such as a CMOS image sensor (CIS), a micro-electro-mechanical system (MEMS), an active element, and a passive element.

The EIC chip 300 of the semiconductor package 1000 may be mounted on the sub package substrate 200. The EIC chip 300 may be spaced apart from the main package substrate 100 with the sub package substrate 200 between the EIC chip 300 and the main package substrate 100.

As shown in FIG. 4, the EIC chip 300 may include a first substrate 310, a first wiring structure 320, and a first through via 310_V. The first substrate 310 of the EIC chip 300 may include an active surface 310_A and an inactive surface opposite to the active surface 310_A. The first wiring structure 320 may be on the active surface 310_A of the first substrate 310. The first through via 310_V may extend from the inactive surface of the first substrate 310 to the active surface 310_A thereof. In some implementations, the first through via 310_V may be electrically connected to the first wiring structure 320 and/or a plurality of individual devices on the active surface 310_A of the first substrate 310.

In some implementations, the EIC chip 300 may be arranged on the sub package substrate 200 such that the active surface 310_A of the first substrate 310 faces the sub package substrate 200. The EIC chip 300 may be arranged on the sub package substrate 200 in a face-down manner.

The first substrate 310 may include a semiconductor material such as silicon (Si). In some implementations, the first substrate 310 may include a semiconductor material such as germanium (Ge).

In some implementations, the EIC chip 300 may include a plurality of individual devices that are used by a plurality of PIC chips 400 to interface with other individual devices. The individual devices of the EIC chip 300 may be arranged on the active surface 310_A of the first substrate 310. For example, the EIC chip 300 may include CMOS drivers, transimpedance amplifiers, and/or the like to perform a function of controlling the high-frequency signaling of each of the PIC chips 400.

The first wiring structure 320 of the EIC chip 300 may include a first wiring pattern 321, a first wiring via 322 connected to the first wiring pattern 321, and a first insulating layer 323 surrounding the first wiring pattern 321 and the first wiring via 322. In some implementations, the first wiring structure 320 may have a multi-layer wiring structure, which includes first insulating layers 323 at different vertical levels and first wiring vias 322 at different vertical levels.

In some implementations, the EIC chip 300 may further include an upper pad 370. The upper pad 370 may be arranged in the top surface of the EIC chip 300 and electrically connected to the first through via 310_V thereof.

In some implementations, the EIC chip 300 may further include a lower pad 380. The lower pad 380 may be arranged in the bottom surface of the EIC chip 300 and electrically connected to the first wiring pattern 321 and/or the first wiring via 322.

In some implementations, the lower pad 380 of the EIC chip 300 may be electrically connected to the upper pad 270 of the sub package substrate 200 through an adhesive film 260. For example, the adhesive film 260 may include an anisotropic conductive film (ACF) or a non-conductive film (NCF). However, a method of connecting the EIC chip 300 to the sub package substrate 200 is not limited to that described above.

The PIC chips 400 of the semiconductor package 1000 may be stacked on the EIC chip 300. In some implementations, the PIC chips 400 may include a first PIC chip 401 and a second PIC chip 402. Although it is illustrated in FIG. 1 that two PIC chips 400 are stacked on one EIC chip 300, the number of PIC chips 400 is not limited thereto.

Each of the PIC chips 400 may receive and output optical signals. For example, each of the PIC chips 400 may convert an electrical signal into an optical signal and transmit the optical signal to the optical fibers 520, and may convert an optical signal received from the optical fibers 520 into an electrical signal and transmit the electrical signal to the EIC chip 300.

The first PIC chip 401 may include a second substrate 411, a second wiring structure 421, a first photoelectric converter 431, and a second through via 411_V.

The second substrate 411 may include a semiconductor material such as silicon (Si). In some implementations, the second substrate 411 may include a semiconductor material such as germanium (Ge).

The second substrate 411 may include an active surface 411_A having a plurality of individual devices formed therein and an inactive surface opposite to the active surface 411_A. The second wiring structure 421 may be on the active surface 411_A of the second substrate 411. The second through via 411_V may extend from the inactive surface of the second substrate 411 to the active surface 411_A thereof. In some implementations, the second through via 411_V may be electrically connected to the second wiring structure 421 and/or the individual devices on the active surface 411_A of the second substrate 411.

The first PIC chip 401 may be arranged on the EIC chip 300 such that the inactive surface of the second substrate 411 faces the EIC chip 300. For example, the first PIC chip 401 may be arranged on the EIC chip 300 in a face-up manner.

Herein, the active surface 411_A of the second substrate 411 may be referred to as the top surface of the second substrate 411 and the inactive surface of the second substrate 411 may be referred to as the bottom surface of the second substrate 411. However, the vertical positions of the active surface 411_A and the inactive surface of the second substrate 411 are not limited thereto.

A first groove 411_G of the first PIC chip 401 may be recessed from/in a first side surface 411_S1 and top surface of the first PIC chip 401. For example, the first groove 411_G of the first PIC chip 401 may extend inward from the top surface of the first PIC chip 401 and may be open toward the first side surface 411_S1 of the first PIC chip 401. For example, the bottom surface of the first groove 411_G of the first PIC chip 401 may meet the first side surface 411_S1 of the first PIC chip 401.

The first groove 411_G of the first PIC chip 401 may be spaced apart from a side surface adjacent to the first side surface 411_S1 of the first PIC chip 401 among the side surfaces of the first PIC chip 401. For example, a third side surface of the first PIC chip 401 may be adjacent to the first side surface 411_S1 of the first PIC chip 401 and spaced apart from the first groove 411_G of the first PIC chip 401.

In some implementations, the first groove 411_G of the first PIC chip 401 may be referred to as a V-groove. When the first groove 411_G of the first PIC chip 401 is viewed from the first side surface 411_S1 of the first PIC chip 401 (e.g., along the X direction), the cross-section of the first groove 411_G thereof may include V-shaped grooves, which are arranged along the first side surface 411_S1 of the first PIC chip 401 and partially overlap with each other. In some implementations, first optical fibers 521 may be respectively mounted on the V-shaped grooves.

The first photoelectric converter 431 of the first PIC chip 401 may convert an optical signal into an electrical signal and an electrical signal into an optical signal. In some implementations, the first photoelectric converter 431 may include a waveguide 4311, a photodetector 4312, a light emitting diode 4313, and a modulator 4314. For example, a light-emitting diode 4313 may include a laser diode.

In the case where an optical signal is input to the first PIC chip 401, the photodetector 4312 may detect the optical signal input to the first PIC chip 401. The first PIC chip 401 may detect the optical signal and convert the optical signal into an electrical signal through the photodetector 4312. The electrical signal output from the photodetector 4312 may be transmitted to the individual devices in the active surface 411_A of the second substrate 411.

In the case where the first PIC chip 401 outputs an optical signal, the individual devices in the active surface 411_A of the second substrate 411 of the first PIC chip 401 may transmit an electrical signal to the modulator 4314. The modulator 4314 may convert the electrical signal into an optical signal by inputting a signal to light emitted by the light emitting diode 4313 according to the electrical signal (e.g., by modulating the light according to the electrical signal).

The waveguide 4311 may correspond to a path through which an optical signal travels in the first PIC chip 401. The waveguide 4311 may provide a path through which an optical signal input to an edge coupler 4311_E travels to the photodetector 4312 or a path through which an optical signal output from the modulator 4314 travels to the edge coupler 4311_E. For example, an optical signal may travel in the top surface of the first PIC chip 401 in the horizontal direction along the waveguide 4311.

The edge coupler 4311_E may be a part of the waveguide 4311. For example, the edge coupler 4311_E may be a region of the waveguide 4311, to which an optical signal emitted from the first optical fiber 521 is incident. The edge coupler 4311_E may be a region of the waveguide 4311, from which an optical signal is emitted to the first optical fiber 521.

In some implementations, the horizontal width of the edge coupler 4311_E may be different from the horizontal width of another region of the waveguide 4311. For example, the edge coupler 4311_E may have a different horizontal width from the other region of the waveguide 4311 for accuracy in transmitting/receiving an optical signal. For example, the horizontal width of the edge coupler 4311_E may decrease toward the first optical fiber 521.

In some implementations, the waveguide 4311 may be arranged such that the edge coupler 4311_E faces the first groove 411_G. For example, the edge coupler 4311_E may be located in an end portion of the first photoelectric converter 431, which is adjacent to the first groove 411_G, among the end portions of the first photoelectric converter 431.

In some implementations, the first photoelectric converter 431 may include a plurality of edge couplers 4311_E. For example, there may be a one-to-one correspondence between the edge couplers 4311_E and first optical fibers 521. For example, when the optical fiber unit 500 includes a plurality of first optical fibers 521, the first optical fibers 521 may respectively face different edge couplers 4311_E. For example, each of the first optical fibers 521 may receive an optical signal from or output an optical signal to one edge coupler 4311_E corresponding thereto among the plurality of edge couplers 4311_E.

In some implementations, the edge coupler 4311_E may have a uniform thickness, e.g., length in the vertical direction (the Z direction). For example, unlike a grating coupler, the edge coupler 4311_E may have a constant thickness throughout the entire area thereof. For example, the thickness of the edge coupler 4311_E may be the same as the thickness of the other region of the waveguide 4311.

Although it is illustrated in FIG. 4 that the first photoelectric converter 431 is buried by a second insulating layer 4213, implementations are not limited thereto. For example, the first photoelectric converter 431 may be covered with an oxide layer different from the second insulating layer 4213. For example, the oxide layer may be formed at a side of the second insulating layer 4213, and the first photoelectric converter 431 may be located in the oxide layer.

The second wiring structure 421 of the first PIC chip 401 may include a second wiring pattern 4211, a second wiring via 4212 connected to the second wiring pattern 4211, and a second insulating layer 4213 surrounding the second wiring pattern 4211 and the second wiring via 4212. In some implementations, the second wiring structure 421 may have a multi-layer wiring structure, which includes second wiring patterns 4211 at different vertical levels and second wiring vias 4212 at different vertical levels.

In some implementations, the first PIC chip 401 may further include a lower pad 481. The lower pad 481 may be arranged in the bottom surface of the first PIC chip 401 and be electrically connected to the second through via 411_V.

In some implementations, the lower pad 481 of the first PIC chip 401 may be electrically connected to the upper pad 370 of the EIC chip 300 through an adhesive film 360. For example, the adhesive film 360 may include an ACF or an NCF.

However, implementations are not limited thereto. For example, the first PIC chip 401 and the EIC chip 300 may be electrically connected to each other through solder ball attachment, direct bonding, or Cu—Cu hybrid bonding. An encapsulation material, such as an underfill, may be between the first PIC chip 401 and the EIC chip 300.

In some implementations, the first PIC chip 401 may further include an upper pad 471. The upper pad 471 may be arranged in the top surface of the second wiring structure 421 of the first PIC chip 401 and be electrically connected to the second wiring pattern 4211 and/or the second wiring via 4212.

The second PIC chip 402 may be mounted on the first PIC chip 401. In some implementations, the second PIC chip 402 may include a third substrate 412, a third through via 412_V, and a second photoelectric converter 432.

The third substrate 412 of the second PIC chip 402 may include a semiconductor material such as silicon (Si). In some implementations, the third substrate 412 may include a semiconductor material such as germanium (Ge).

The third substrate 412 may include an active surface 412_A having a plurality of individual devices formed therein and an inactive surface opposite to the active surface 412_A. The third through via 412_V may extend from the inactive surface of the third substrate 412 to the active surface 412_A thereof. In some implementations, the third through via 412_V may be electrically connected to the individual devices on the active surface 412_A of the third substrate 412.

The second PIC chip 402 may be arranged on the first PIC chip 401 such that the inactive surface of the third substrate 412 faces the first PIC chip 401. For example, the second PIC chip 402 may be arranged on the first PIC chip 401 in a face-up manner.

The second PIC chip 402 may be offset-stacked on the first PIC chip 401. A plurality of PIC chips 400 may be stacked in a stepped pattern. The second PIC chip 402 may be stacked on the first PIC chip 401 such that at least a portion of the bottom surface of the first groove 411_G of the first PIC chip 401 is exposed in the Z-direction outside the second PIC chip 402.

The second PIC chip 402 may be offset from the first PIC chip 401 such that a second side surface 412_S1 of the second PIC chip 402 is located above the top surface of the first PIC chip 401.

In some implementations, the bottom surface of the first groove 411_G of the first PIC chip 401 may be entirely exposed in the Z-direction outside the second PIC chip 402. For example, the second PIC chip 402 may be offset from the first PIC chip 401 by a length, by which the first groove 411_G of the first PIC chip 401 is recessed from the first side surface 411_S1 of the first PIC chip 401, or more.

A second groove 412_G of the second PIC chip 402 may be recessed from/in the second side surface 412_S1 and the top surface of the second PIC chip 402. For example, the second groove 412_G of the second PIC chip 402 may extend inward from the top surface of the second PIC chip 402 and may be open toward the second side surface 412_S1 of the second PIC chip 402. For example, the bottom surface of the second groove 412_G of the second PIC chip 402 may meet the second side surface 412_S1 of the second PIC chip 402.

The second groove 412_G of the second PIC chip 402 may be spaced apart from a side surface adjacent to the second side surface 412_S1 of the second PIC chip 402 among the side surfaces of the second PIC chip 402. For example, a fourth side surface of the second PIC chip 402 may be adjacent to the second side surface 412_S1 of the second PIC chip 402 and apart from the second groove 412_G of the second PIC chip 402.

In some implementations, the second groove 412_G of the second PIC chip 402 may be referred to as a V-groove. When the second groove 412_G of the second PIC chip 402 is viewed from the second side surface 412_S1 of the second PIC chip 402 (e.g., along the X direction), the cross-section of the second groove 412_G thereof may include V-shaped grooves, which are arranged along the second side surface 412_S1 of the second PIC chip 402 and partially overlap with each other. In some implementations, second optical fibers 522 may be respectively mounted on the V-shaped grooves.

In some implementations, a direction in which the first side surface 411_S1 of the first PIC chip 401 faces may be the same as a direction in which the second side surface 412_S1 of the second PIC chip 402 faces.

In some implementations, the first side surface 411_S1 of the first PIC chip 401 may be parallel with the second side surface 412_S1 of the second PIC chip 402 and the second side surface 412_S1 of the second PIC chip 402 may be located above the top surface of the first PIC chip 401.

In some implementations, the first side surface 411_S1 of the first PIC chip 401 and the second side surface 412_S1 of the second PIC chip 402 may face a frame 510 of the optical fiber unit 500.

In some implementations, a distance L_401 between the first side surface 411_S1 of the first PIC chip 401 and the frame 510 of the optical fiber unit 500 may be different from a distance L_402 between the second side surface 412_S1 of the second PIC chip 402 and the frame 510 of the optical fiber unit 500.

For example, the distance L_402 between the second side surface 412_S1 of the second PIC chip 402 and the frame 510 of the optical fiber unit 500 may be greater than the distance L_401 between the first side surface 411_S1 of the first PIC chip 401 and the frame 510 of the optical fiber unit 500.

For example, the first PIC chip 401 may be closer to the frame 510 of the optical fiber unit 500 than the second PIC chip 402. For example, the second PIC chip 402 may be offset-stacked on the first PIC chip 401 to be farther away from the frame 510 of the optical fiber unit 500.

In some implementations, the second groove 412_G of the second PIC chip 402 and the first groove 411_G of the first PIC chip 401 may be arranged in line with one another in the vertical direction (the Z direction). For example, when the first PIC chip 401 and the second PIC chip 402 are viewed from the first side surface 411_S1 of the first PIC chip 401 (e.g., along the X direction), the first groove 411_G and the second groove 412_G may be positioned on a straight line in the vertical direction (the Z direction).

For example, the third side surface of the first PIC chip 401 may be coplanar with the fourth side surface of the second PIC chip 402 and the distance between the first groove 411_G and the third side surface may be substantially the same as the distance between the second groove 412_G and the fourth side surface.

In some implementations, a region of the first groove 411_G, which is adjacent to the first side surface 411_S1 of the first PIC chip 401, may be exposed to the outside. For example, the second PIC chip 402 may be stacked on the first PIC chip 401 with an offset in the first horizontal direction (the X direction) such that a portion of the first groove 411_G of the first PIC chip 401 is vertically exposed outside the second PIC chip 402.

The second photoelectric converter 432 of the second PIC chip 402 may convert an optical signal into an electrical signal and an electrical signal into an optical signal. In some implementations, the second photoelectric converter 432 may include a waveguide 4321, a photodetector 4322, a light emitting diode 4323, and a modulator 4324. For example, a light-emitting diode 4323 may include a laser diode.

An edge coupler 4321_E may be located at an end of the waveguide 4321 of the second photoelectric converter 432. The photodetector 4322, the light emitting diode 4323, and the modulator 4324 may be located at the opposite end of the waveguide 4321 of the second photoelectric converter 432.

The edge coupler 4321_E may be a part of the waveguide 4321. For example, the edge coupler 4321_E may be a region of the waveguide 4321, to which an optical signal emitted from the second optical fiber 522 is incident. The edge coupler 4321_E may be a region of the waveguide 4321, from which an optical signal is emitted to the second optical fiber 522.

In some implementations, the waveguide 4321 may be arranged such that the edge coupler 4321_E faces the second groove 412_G of the second PIC chip 402. For example, the edge coupler 4321_E may be located in an end portion of the second photoelectric converter 432, which is adjacent to the second groove 412_G, among the end portions of the second photoelectric converter 432.

In some implementations, the photodetector 4322, the light emitting diode 4323, and the modulator 4324 of the second photoelectric converter 432 may be substantially the same as the photodetector 4312, the light emitting diode 4313, and the modulator 4314 of the first photoelectric converter 431.

The second photoelectric converter 432 may be buried by a third insulating layer 4223. The third insulating layer 4223 may protect the second photoelectric converter 432 from the outside. In some implementations, the material of the third insulating layer 4223 may be the same as the material of the second insulating layer 4213.

The second PIC chip 402 may further include a third wiring structure. The third wiring structure of the second PIC chip 402 may be located on the active surface 412_A of the third substrate 412. The third wiring structure of the second PIC chip 402 may be substantially the same as the second wiring structure 421 of the first PIC chip 401.

In some implementations, the second PIC chip 402 may further include a lower pad 482. The lower pad 482 may be arranged on the bottom surface of the second PIC chip 402 and be electrically connected to the third through via 412_V.

In some implementations, the lower pad 482 of the second PIC chip 402 may be electrically connected to the upper pad 471 of the first PIC chip 401 through an adhesive film 460. For example, the adhesive film 460 may include an ACF or an NCF.

However, implementations are not limited thereto. For example, the first PIC chip 401 and the second PIC chip 402 may be electrically connected to each other through solder ball attachment, direct bonding, or Cu—Cu hybrid bonding. An encapsulation material, such as an underfill, may be between the first PIC chip 401 and the second PIC chip 402.

The optical fiber unit 500 of the semiconductor package 1000 may be removably mounted on the plurality of PIC chips 400. For example, each of a plurality of optical fibers 520 of the optical fiber unit 500 may be mounted to one of the grooves of the PIC chips 400.

The optical fiber unit 500 may include the frame 510 and the optical fibers 520 extending from the frame 510 toward the PIC chips 400.

The frame 510 of the optical fiber unit 500 may be located outside the main package substrate 100. For example, the frame 510 may be spaced apart from a side surface of the main package substrate 100 and a side surface of the sub package substrate 200 in the horizontal direction.

The optical fibers 520 may be spaced apart from each other in the vertical direction (the Z direction). In some implementations, the optical fibers 520 may be arranged in line with on another in the vertical direction (the Z direction).

In some implementations, the optical fibers 520 may include the first optical fiber 521 and the second optical fiber 522. The first optical fiber 521 may extend from the frame 510 such that an end of the first optical fiber 521 is located in the first groove 411_G of the first PIC chip 401. The second optical fiber 522 may extend from the frame 510 such that an end of the second optical fiber 522 is located in the second groove 412_G of the second PIC chip 402.

In some implementations, the first optical fiber 521 may face the edge coupler 4311_E of the first PIC chip 401 and the second optical fiber 522 may face the edge coupler 4321_E of the second PIC chip 402.

In some implementations, the second optical fiber 522 may be fixed to the second groove 412_G by a clamping lead 530. For example, the clamping lead 530 may be in contact with the second optical fiber 522 and may function as the ceiling of the second groove 412_G.

In some implementations, transparent epoxy may be between the first optical fiber 521 and the first groove 411_G and between the second optical fiber 522 and the second groove 412_G. For example, the transparent epoxy may transmit an optical signal and fix the positions of the first optical fiber 521 and the second optical fiber 522.

The first optical fiber 521 and the second optical fiber 522 may be spaced apart from each other in the vertical direction (the Z direction). The first optical fiber 521 may be vertically between the first PIC chip 401 and the second PIC chip 402 and the second optical fiber 522 may be located above the second PIC chip 402.

The first optical fiber 521 may include a first core layer 521_1 and a first clad layer 521_2 surrounding the first core layer 521_1. The second optical fiber 522 may include a second core layer 522_1 and a second clad layer 522_2 surrounding the second core layer 522_1. The first and second core layers 521_1 and 522_1 may have a relatively large refractive index and the first and second clad layers 521_2 and 522_2 may have a relatively small refractive index. An optical signal input to the first and second core layers 521_1 and 522_1 may travel along the first and second core layers 521_1 and 522_1, which have a large refractive index. An optical signal traveling from the first or second core layer 521_1 or 522_1 to the first or second clad layer 521_2 or 522_2 may be totally reflected from the first or second clad layer 521_2 or 522_2 because of the difference in the refractive index between the first or second core layer 521_1 or 522_1 and the first or second clad layer 521_2 or 522_2 and may thus travel along the first or second core layer 521_1 or 522_1.

The first core layer 521_1 of the first optical fiber 521 may be at the same vertical level as the edge coupler 4311_E of the first PIC chip 401. The second core layer 522_1 of the second optical fiber 522 may be at the same vertical level as the edge coupler 4321_E of the second PIC chip 402. Herein, the term “vertical level” refers to the distance from the bottom surface of the main package substrate 100.

Herein, the term “extension length of an optical fiber” refers to the distance from a side surface of the frame 510 to an end of the optical fiber in a groove of a PIC chip.

An extension length L_521 of the first optical fiber 521 may be different from an extension length L_522 of the second optical fiber 522. For example, the extension length L_521 of the first optical fiber 521 may be less than the extension length L_522 of the second optical fiber 522.

In some implementations, the difference between the extension length L_521 of the first optical fiber 521 and the extension length L_522 of the second optical fiber 522 may be greater than the offset between the first PIC chip 401 and the second PIC chip 402. The difference between the extension length L_521 of the first optical fiber 521 and the extension length L_522 of the second optical fiber 522 may be greater than each of the distance L_401 between the first PIC chip 401 and the frame 510 and the distance L_402 between the second PIC chip 402 and the frame 510.

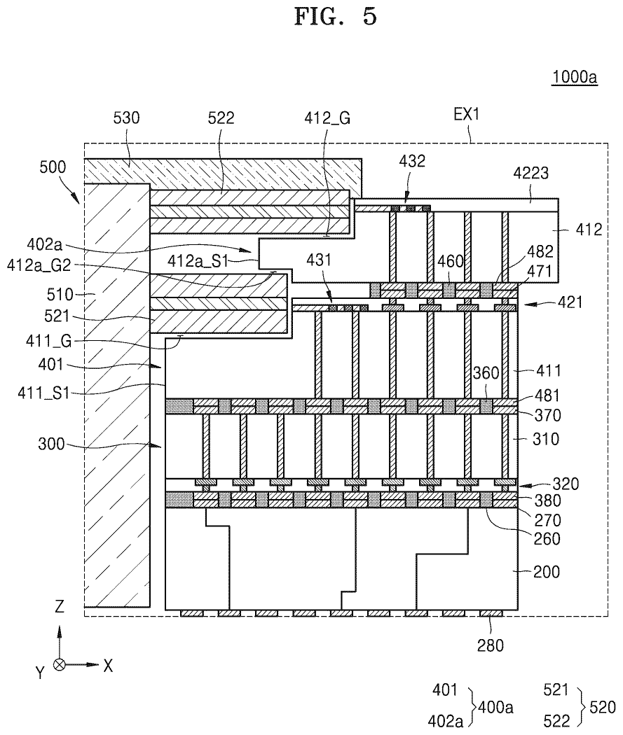

FIG. 5 is an enlarged view of an example of the region EX1 in FIG. 3 in a semiconductor package 1000a according to some implementations.

The elements and characteristics of the semiconductor package 1000a, and the materials of the elements, are substantially the same as or similar to those described above with reference to FIG. 1. For convenience of description, therefore, the semiconductor package 1000a is described with a focus on differences from the semiconductor package 1000 of FIG. 1, and the elements and characteristics can be the same except where noted otherwise.

A plurality of PIC chips 400a of the semiconductor package 1000a may be stacked on the EIC chip 300 with an offset from each other. For example, the PIC chips 400a may be stacked on the EIC chip 300 in a stepped pattern.

The PIC chips 400a may include the first PIC chip 401 and a second PIC chip 402a. However, the PIC chips 400a may include at least three PIC chips.

Each of the PIC chips except for the lowest PIC chip 401 among the PIC chips 400a may include a groove extending inward at the bottom thereof. Hereinafter, the second PIC chip 402a is described as an example of a PIC chip including a groove extending inward at the bottom thereof among the PIC chips 400a.

The second PIC chip 402a may include a third groove 412a_G2, which extends inward at the bottom of the second PIC chip 402a and opens to a second side surface 412a_S1 of the second PIC chip 402a. The third groove 412a_G2 may be recessed from/in the bottom surface and the second side surface 412a_S1 of the second PIC chip 402a.

For example, the third groove 412a_G2 may be located above the first groove 411_G. Accordingly, the ceiling of the third groove 412a_G2 may also function as the ceiling of the first groove 411_G.

In some implementations, the third groove 412a_G2 and the first groove 411_G may be in line with one another in the vertical direction (the Z direction). For example, when the first PIC chip 401 and the second PIC chip 402a are viewed from the frame 510 (e.g., along the X direction), the third groove 412a_G2 and the first groove 411_G may be in line in the vertical direction (the Z direction).

The first optical fiber 521 of the optical fiber unit 500 may be located in the first groove 411_G and the third groove 412a_G2. For example, the first optical fiber 521 may be between the first groove 411_G of the first PIC chip 401 and the third groove 412a_G2 of the second PIC chip 402a.

A portion of the first optical fiber 521 may be located below the second PIC chip 402a such that the offset between the second PIC chip 402a and the first PIC chip 401 (e.g., difference in each chip's 401, 402a spacing from the frame 510 in the X direction) may be decreased, advantageously reducing the size of the semiconductor package 1000a.

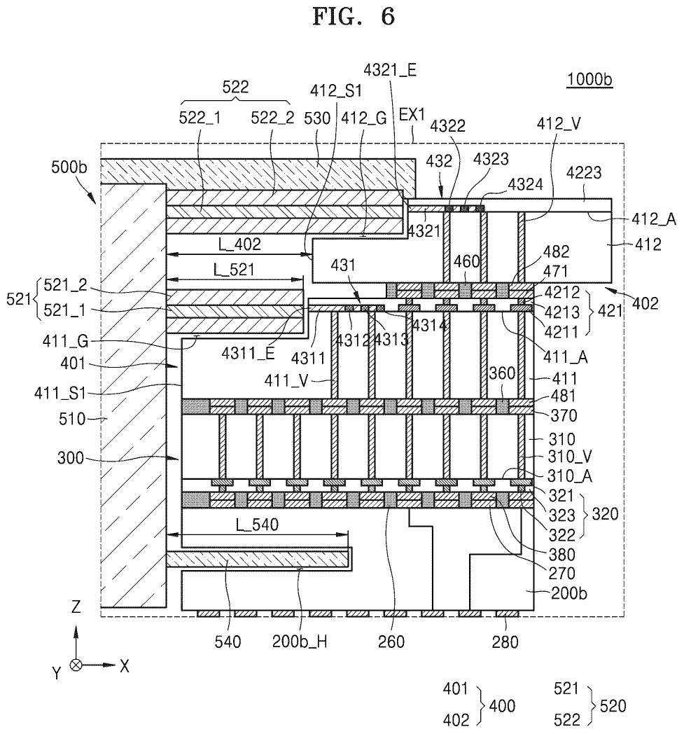

FIG. 6 is an enlarged view of the region EX1 in FIG. 3 in a semiconductor package 1000b according to some implementations.

The elements and characteristics of the semiconductor package 1000b, and the materials of the elements, are substantially the same as or similar to those described above with reference to FIG. 1. For convenience of description, therefore, the semiconductor package 1000b is described with a focus on differences from the semiconductor package 1000 of FIG. 1, and the elements and characteristics can be the same except where noted otherwise.

A sub package substrate 200b of the semiconductor package 1000b may include an alignment hole 200b_H, which extends inward from a side surface of the sub package substrate 200b. An optical fiber unit 500b of the semiconductor package 1000b may include an alignment pin 540, which protrudes from the frame 510 and is located in the alignment hole 200b_H.

The shape of the alignment hole 200b_H may correspond to the shape of the alignment pin 540. For example, when the alignment pin 540 has a shape having a vertical width decreasing away from the frame 510, the vertical width of the alignment hole 200b_H may decrease away from the side surface of the sub package substrate 200b. Although it is illustrated in FIG. 6 that the alignment pin 540 and the alignment hole 200b_H have a rectangular pillar shape, the shape of the alignment pin 540 and the alignment hole 200b_H is not limited thereto.

In some implementations, an extension length L_540 of the alignment pin 540 may be different from the extension length L_521 of the first optical fiber 521. For example, the extension length L_540 of the alignment pin 540 may be greater than the extension length L_521 of the first optical fiber 521. For example, in a process of combining the optical fiber unit 500b with the PIC chips 400 by mating the optical fiber unit 500b with the PIC chips 400 in the X direction, the alignment pin 540 may enter the alignment hole 200b_H of the sub package substrate 200b before the first optical fiber 521 enters the first groove 411_G.

In some implementations, the distance L_402 between the second PIC chip 402 and the frame 510 of the optical fiber unit 500b may be less than the extension length L_540 of the alignment pin 540 of the optical fiber unit 500b. For example, in the process of combining the optical fiber unit 500b with the PIC chips 400, the alignment pin 540 may enter the alignment hole 200b_H of the sub package substrate 200b before the second optical fiber 522 enters the second groove 412_G.

In the process of combining the optical fiber unit 500b with the PIC chips 400, the optical fiber unit 500b may be pre-aligned with the PIC chips 400 when the alignment pin 540 is inserted into the alignment hole 200b_H of the sub package substrate 200b. Accordingly, in a process of respectively locating the first optical fiber 521 and the second optical fiber 522 in the first groove 411_G and the second groove 412_G, an alignment error between the first optical fiber 521 and the first groove 411_G and an alignment error between the second optical fiber 522 and the second groove 412_G may be relatively decreased.

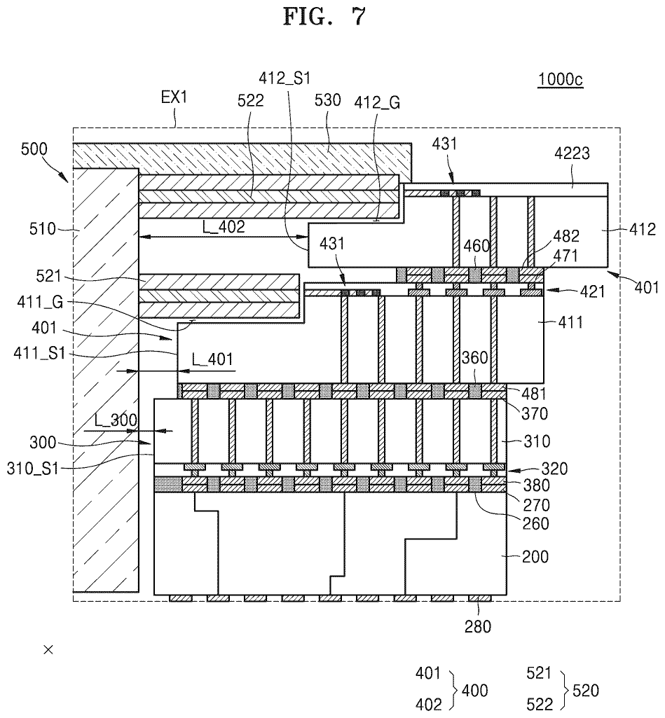

FIG. 7 is an enlarged view of the region EX1 in FIG. 3 in a semiconductor package 1000c according to some implementations.

The elements and characteristics of the semiconductor package 1000c, and the materials of the elements, are substantially the same as or similar to those described above with reference to FIG. 1. For convenience of description, therefore, the semiconductor package 1000c with a focus on the differences from the semiconductor package 1000 of FIG. 1, and the elements and characteristics can be the same except where noted otherwise.

The first PIC chip 401 of the semiconductor package 1000c may be offset-stacked on the EIC chip 300. For example, the first PIC chip 401 and the second PIC chip 402 may be stacked on the EIC chip 300 in a stepped pattern.

In some implementations, the distance L_402 between the second side surface 412_S1 of the second PIC chip 402 and the frame 510 of the optical fiber unit 500 may be greater than the distance L_401 between the first side surface 411_S1 of the first PIC chip 401 and the frame 510. The distance L_401 between the first side surface 411_S1 of the first PIC chip 401 and the frame 510 may be greater than a distance L_300 between a first surface 310_S1 of the EIC chip 300 and the frame 510. A side surface facing the frame 510 of the optical fiber unit 500 among the side surfaces of the EIC chip 300 may be the first surface 310_S1 of the EIC chip 300.

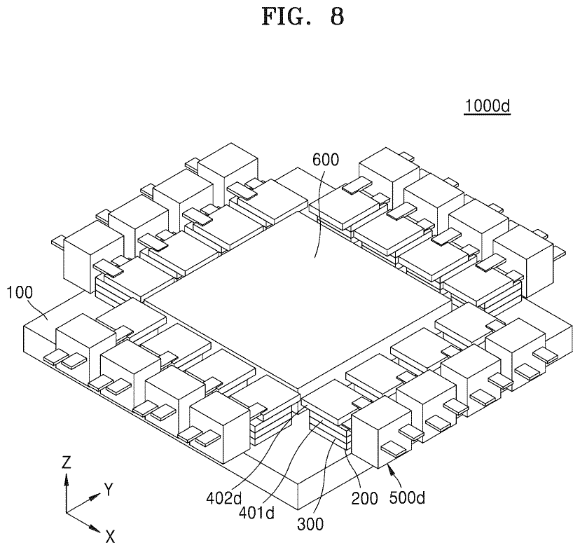

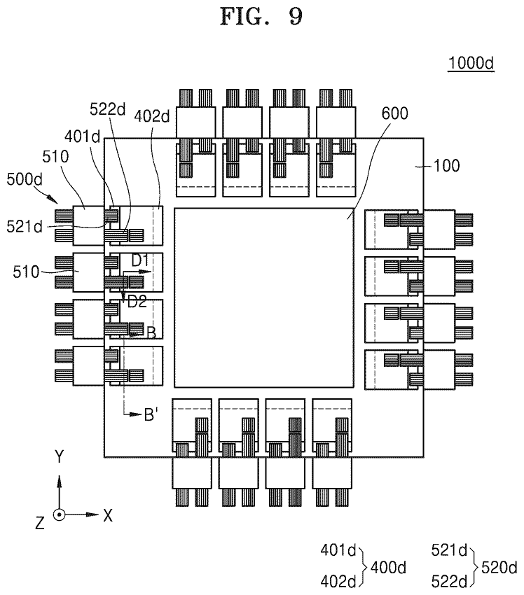

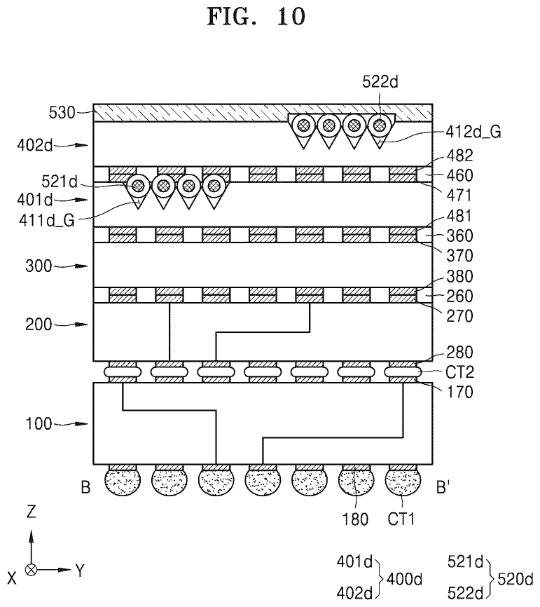

FIG. 8 is a schematic perspective view of a semiconductor package 1000d according to some implementations. FIG. 9 is a schematic plan view of the semiconductor package 1000d of FIG. 8. FIG. 10 is a schematic cross-sectional view of the semiconductor package 1000d of FIG. 9, taken along line B-B′ in FIG. 9.

The elements and characteristics of the semiconductor package 1000d, and the materials of the elements, are substantially the same as or similar to those described above with reference to FIG. 1. For convenience of description, therefore, the semiconductor package 1000d is described with a focus on the differences from the semiconductor package 1000 of FIG. 1, and the elements and characteristics can be the same except where noted otherwise.

A plurality of PIC chips 400d of the semiconductor package 1000d may include a first PIC chip 401d and a second PIC chip 402d. The frame 510 of an optical fiber unit 500d may be spaced apart from the PIC chips 400d in a horizontal direction.

The horizontal direction in which the frame 510 of an optical fiber unit 500d is apart from the PIC chips 400d is defined as a first direction D1, and a horizontal direction that is perpendicular to the first direction D1 is defined as a second direction D2.

The second PIC chip 402d may be stacked on the first PIC chip 401d with an offset in the first direction D1. For example, the second PIC chip 402d may be farther away from the frame 510 of an optical fiber unit 500d than the first PIC chip 401d.

A first groove 411d_G of the first PIC chip 401d and a second groove 412d_G of the second PIC chip 402d may be arranged to be offset from each other in the vertical direction (the Z direction). For example, the first groove 411d_G of the first PIC chip 401d and the second groove 412d_G of the second PIC chip 402d may be spaced apart from each other in the vertical direction (the Z direction) and in the second direction D2 (e.g., the Y direction as shown in FIG. 10).

For example, when the PIC chips 400d are viewed from the frame 510 of an optical fiber unit 500d (e.g., along the X direction), the first groove 411d_G of the first PIC chip 401d and the second groove 412d_G of the second PIC chip 402d may not be on a common straight line in the vertical direction (the Z direction).

For example, the distance between a side surface of the first PIC chip 401d adjacent to the first surface 411_S1 (as shown in FIG. 3) of the first PIC chip 401d and the first groove 411d_G of the first PIC chip 401d may be different from the distance between a side surface of the second PIC chip 402d adjacent to the second side surface 412_S1 (as shown in FIG. 3) of the second PIC chip 402d and the second groove 412d_G of the second PIC chip 402d.

In some implementations, the first groove 411d_G of the first PIC chip 401d may partially overlap the second groove 412d_G of the second PIC chip 402d in the vertical direction (the Z direction). For example, among the sidewalls defining the first groove 411d_G of the first PIC chip 401d, one of two opposite sidewalls facing each other in the second direction D2 may overlap (e.g., be under) the second groove 412d_G of the second PIC chip 402d in the vertical direction (the Z direction) and the other sidewall of the two opposite sidewalls may not overlap the second groove 412d_G of the second PIC chip 402d.

However, implementations are not limited thereto. As shown in FIG. 10, the first groove 411d_G of the first PIC chip 401d and the second groove 412d_G of the second PIC chip 402d may not overlap at all in the vertical direction (the Z direction), e.g., may be fully spaced apart in the Y direction

The optical fiber unit 500d may include a plurality of optical fibers 520d. The optical fibers 520d may include a first optical fiber 521d, which protrudes from the frame 510 and has an end located in the first groove 411d_G, and a second optical fiber 522d, which protrudes from the frame 510 and has an end located in the second groove 412d_G.

The first optical fiber 521d may be spaced apart from the second optical fiber 522d in the vertical direction (the Z direction) and the second direction D2. For example, the first optical fiber 521d and the second optical fiber 522d may be arranged to be offset from each other in the vertical direction (the Z direction) and in the second direction D2.

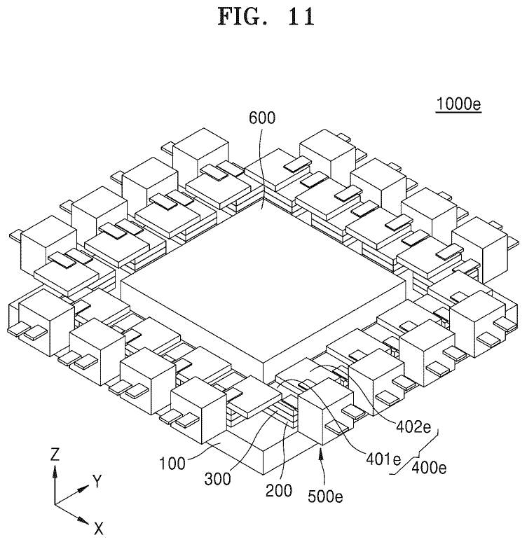

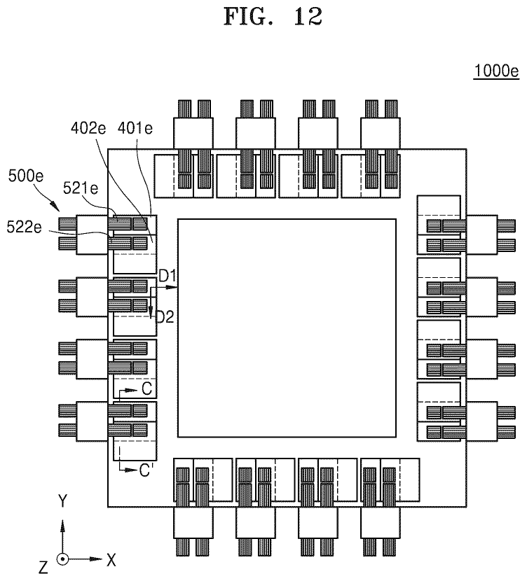

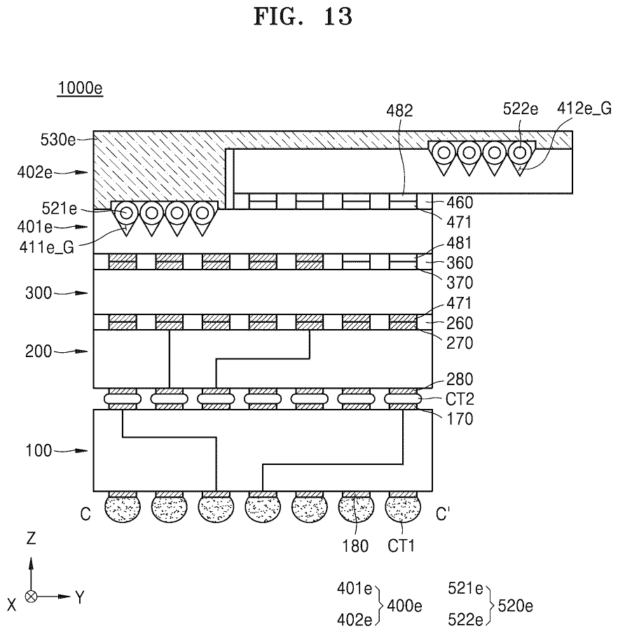

FIG. 11 is a schematic perspective view of a semiconductor package 1000e according to some implementations. FIG. 12 is a schematic plan view of the semiconductor package 1000e of FIG. 11. FIG. 13 is a schematic cross-sectional view of the semiconductor package 1000e of FIG. 12, taken along line C-C′ in FIG. 12.

The elements and characteristics of the semiconductor package 1000e, and the materials of the elements, are substantially the same as or similar to those described above with reference to FIG. 1. For convenience of description, therefore, the semiconductor package 1000e is described with a focus on the differences from the semiconductor package 1000 of FIG. 1, and the elements and characteristics can be the same except where noted otherwise.

A plurality of PIC chips 400e of the semiconductor package 1000e may include a first PIC chip 401e and a second PIC chip 402e. The frame 510 of an optical fiber unit 500e may be spaced apart from the PIC chips 400e in a horizontal direction.

The horizontal direction in which the frame 510 of an optical fiber unit 500e is apart from the PIC chips 400e is defined as the first direction D1 and a horizontal direction that is perpendicular to the first direction D1 is defined as the second direction D2.

The first PIC chip 401e and the second PIC chip 402e may be offset from each other in the second direction D2. For example, the second PIC chip 402e may be stacked on the first PIC chip 401e with an offset in the second direction D2. The second PIC chip 402e may be offset from the first PIC chip 401e in the second direction D2 such that a first groove 411e_G of the first PIC chip 401e is exposed in the vertical direction outside the second PIC chip 402e.

In some implementations, the second PIC chip 402e may be offset from the first PIC chip 401e such that a side surface of the second PIC chip 402e adjacent to the second side surface 412_S1 of the second PIC chip 402e is located above the top surface of the first PIC chip 401e.

In some implementations, the distance between the first PIC chip 401e and the frame 510 may be the same as the distance between the second PIC chip 402e and the frame 510. For example, the second PIC chip 402e may be offset from the first PIC chip 401e only in the second direction D2 but not in the first direction D1.

The first groove 411e_G of the first PIC chip 401e and a second groove 412e_G of the second PIC chip 402e may be arranged to be offset from each other in the vertical direction (the Z direction). For example, the first groove 411e_G of the first PIC chip 401e and the second groove 412e_G of the second PIC chip 402e may be spaced apart from each other in the vertical direction (the Z direction) and the second direction D2.

In some implementations, the first groove 411e_G of the first PIC chip 401e may be completely exposed in the upward vertical direction. For example, the second PIC chip 402e may not be located above the first groove 411e_G of the first PIC chip 401e. For example, the second PIC chip 402e may not be located above opposite sidewalls, which face each other in the second direction D2 among sidewalls forming the first groove 411e_G of the first PIC chip 401e.

In some implementations, the first groove 411e_G of the first PIC chip 401e and the second groove 412e_G of the second PIC chip 402e may not overlap each other at all in the vertical direction (the Z direction). For example, two opposite sidewalls, which face each other in the second direction D2 among the sidewalls forming the first groove 411e_G of the first PIC chip 401e, may not overlap the second groove 412e_G of the second PIC chip 402e in the vertical direction (the Z direction) (e.g., may not be under the second groove 412e_G).

In some implementations, the second groove 412e_G of the second PIC chip 402e may overlap the first groove 411e_G of the first PIC chip 401e in the vertical direction (the Z direction). Accordingly, in some implementations, the mechanical stability of the semiconductor package 1000e may increase when a second optical fiber 522e is mounted on the second groove 412e_G of the second PIC chip 402e.

In some implementations, the optical fiber unit 500e may include a plurality of optical fibers 520e and the frame 510. The optical fibers 520e may include a first optical fiber 521e, which protrudes from the frame 510 and has an end located in the first groove 411e_G, and a second optical fiber 522e, which protrudes from the frame 510 and has an end located in the second groove 412e_G.

The first optical fiber 521e may be spaced apart from the second optical fiber 522e in the vertical direction (the Z direction) and the second direction D2. In other words, the first optical fiber 521e and the second optical fiber 522e may be arranged to be offset from each other in the vertical direction (the Z direction) and in the second direction D2.

In some implementations, the extension length (L_521 in FIG. 4) of the first optical fiber 521e may be the same as the extension length (L_522 in FIG. 4) of the second optical fiber 522e. The first PIC chip 401e and the second PIC chip 402e may be offset from each other in the second direction D2 (e.g., and not in the first direction D1), and accordingly, the extension length of the first optical fiber 521e may be the same as the extension length of the second optical fiber 522e.

In some implementations, a clamping lead 530e of the optical fiber unit 500e may be in contact with top surface of the first PIC chip 401e and the top surface of the second PIC chip 402e. The clamping lead 530e may function as the ceiling of the first groove 411e_G and the second groove 412e_G. The clamping lead 530e may fix the first optical fiber 521e to the first groove 411e_G and the second optical fiber 522e to the second groove 412e_G.

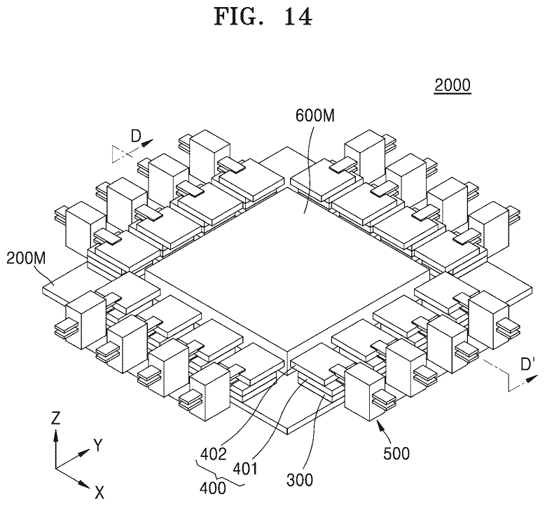

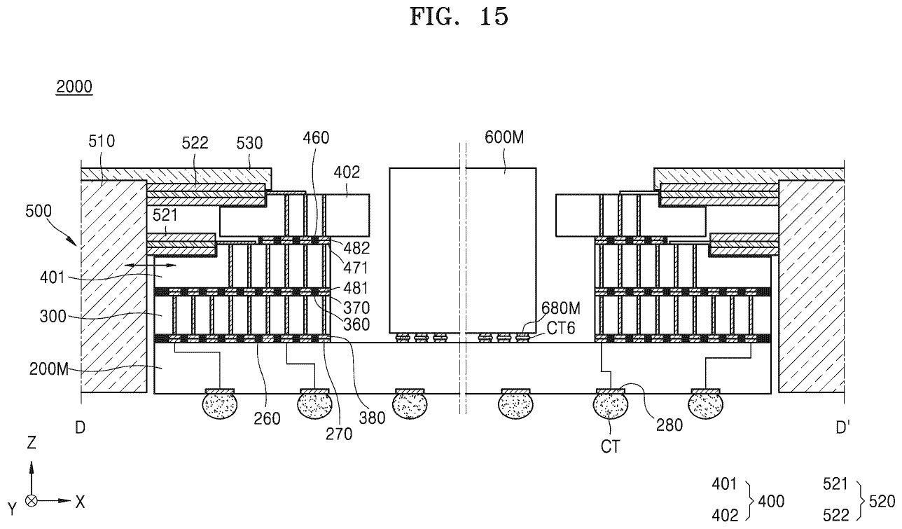

FIG. 14 is a schematic perspective view of a semiconductor package 2000 according to some implementations. FIG. 15 is a schematic cross-sectional view of the semiconductor package 2000 of FIG. 14, taken along line D-D′ in FIG. 14.

The elements and characteristics of the semiconductor package 2000, and the materials of the elements, are substantially the same as or similar to those described above with reference to FIG. 1. For convenience of description, therefore, the semiconductor package 2000 is described with a focus on differences from the semiconductor package 1000 of FIG. 1, and the elements and characteristics can be the same except where noted otherwise.

The semiconductor package 2000 may not include a main package substrate (100 in FIG. 1). A plurality of EIC chips 300 may be mounted on one sub package substrate 200M. For example, the EIC chips 300 may be arranged along the edges of the top surface of the sub package substrate 200M. For example, the EIC chips 300 and the plurality of PIC chips 400 may be located in an edge portion of the sub package substrate 200M.

Although it is illustrated in FIG. 14 that four EIC chips 300 are mounted on each of the edges of the top surface of the sub package substrate 200M, the number of EIC chips 300 is not limited thereto.

An external connection terminal CT may be attached to the lower pad 280 of the sub package substrate 200M. The external connection terminal CT may be configured to electrically and physically connect the sub package substrate 200M to an external device, on which the sub package substrate 200M is mounted. For example, the external connection terminal CT may be formed from a solder ball or a solder bump.

A semiconductor chip 600M may be mounted on the sub package substrate 200M. The semiconductor chip 600M may be apart from the EIC chips 300 in the horizontal direction. For example, the semiconductor chip 600M may be located in a central portion of the sub package substrate 200M. A lower pad 680M of the semiconductor chip 600M may be electrically connected to the upper pad 270 of the sub package substrate 200M through the connection terminal CT6.

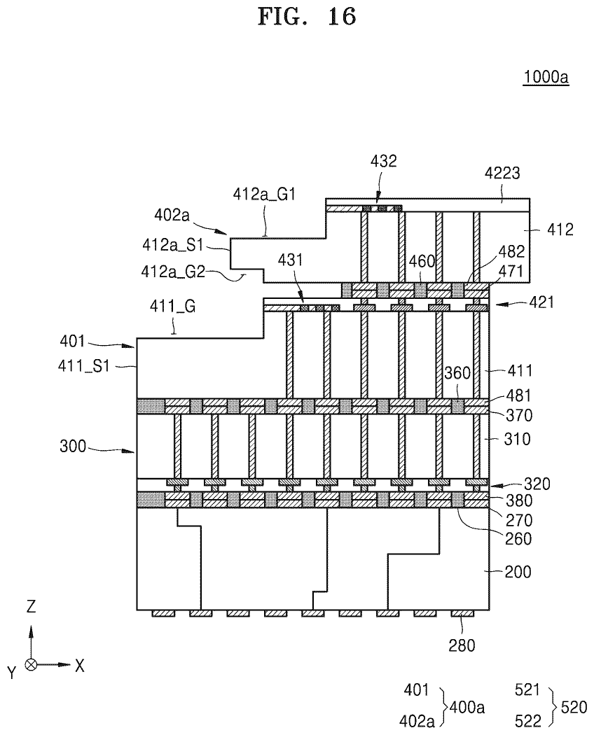

FIGS. 16 to 18 are diagrams of stages in a method of manufacturing a semiconductor package, according to some implementations. In detail, FIGS. 16 to 18 are enlarged views of the region EX1 in FIG. 3 in stages of attaching the optical fiber unit 500 to the PIC chips 400a in a method of manufacturing the semiconductor package 1000a of FIG. 5. However, in some implementations, the method illustrated in FIGS. 16 to 18 can be applied to other semiconductor packages described herein, such as semiconductor packages 1000, 1000b, 1000c, 1000d, 1000e, and 2000.

Referring to FIG. 16, the EIC chip 300 and the PIC chips 400a may be stacked on the sub package substrate 200. The PIC chips 400a may include the first PIC chip 401 and the second PIC chip 402a, which is offset-stacked on the first PIC chip 401.

An upper portion of the first groove 411_G of the first PIC chip 401 may be partially exposed to the outside (e.g., may be partially under, and partially not under, the second PIC chip 402a). In some implementations, the third groove 412a_G2 of the second PIC chip 402a may be located above the first groove 411_G of the first PIC chip 401. For example, the first groove 411_G of the first PIC chip 401 may include a region, which has a bottom surface exposed to the outside, and a region, above which the third groove 412a_G2 of the second PIC chip 402a is located.

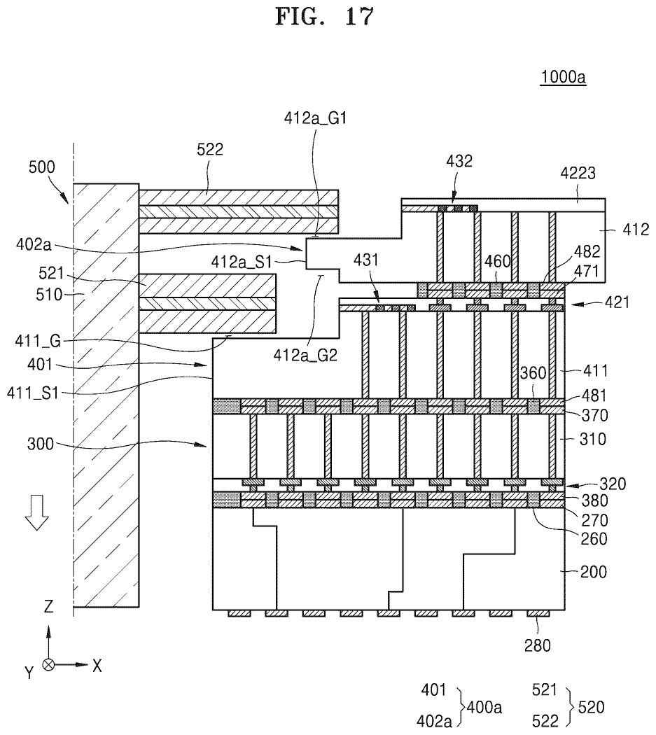

Referring to FIG. 17, the optical fiber unit 500 may be moved in the vertical direction (the Z direction) such that a portion of the first optical fiber 521 and a portion of the second optical fiber 522 are respectively located in the first groove 411_G of the first PIC chip 401 and a second groove 412a_G1 of the second PIC chip 402a. For example, the optical fiber unit 500 may be moved in the vertical direction (the Z direction) such that the first optical fiber 521 is located in a region of the first groove 411_G, in which an upper portion of the first groove 411_G is exposed to the outside (e.g., a region that is not under the second PIC chip 402a).

Because the first groove 411_G of the first PIC chip 401 is exposed, the first optical fiber 521 may be moved downward in the vertical direction (the Z direction) from above the first PIC chip 401 so as to contact the bottom surface of the first groove 411_G. The second optical fiber 522 may be moved downward in the vertical direction (the Z direction) from above the second PIC chip 402a so as to contact the bottom surface of the second groove 412a_G1.

Although it has been described that the optical fiber unit 500 is moved in the vertical direction (the Z direction) to respectively locate the first optical fiber 521 and the second optical fiber 522 in the first groove 411_G and the second groove 412a_G1, the optical fiber unit 500 may be moved in the vertical direction (the Z direction) to locate the first optical fiber 521 or the second optical fiber 522 in the first groove 411_G or the second groove 412a_G1.

Because the second PIC chip 402a is offset-stacked on the first PIC chip 401, the alignment between the optical fiber unit 500 and the PIC chips 400a in the vertical direction (the Z direction) may be carried out first in a process of attaching the optical fiber unit 500 to the PIC chips 400a. Accordingly, the process of attaching the optical fiber unit 500 to the PIC chips 400a may be facilitated and simplified.

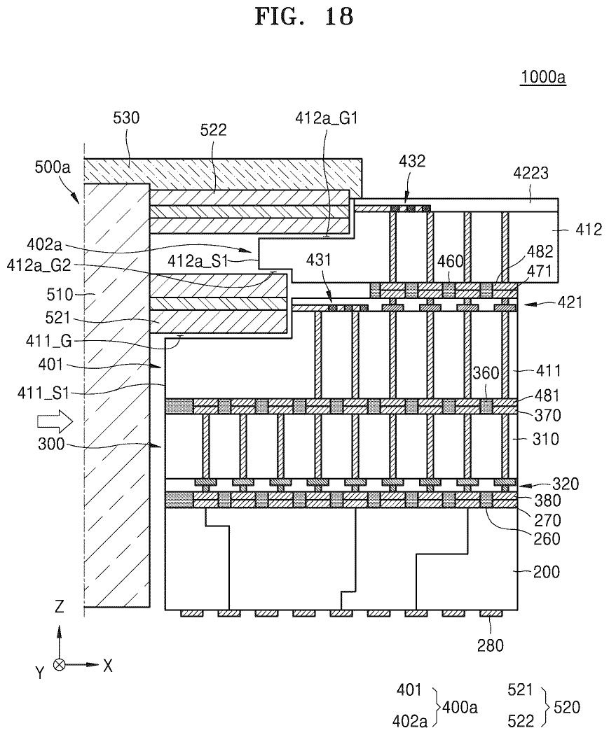

Referring to FIG. 18, the optical fiber unit 500 may be moved in the horizontal direction to locate the first optical fiber 521 in the third groove 412a_G2. For example, the distance between the first optical fiber 521 and the first photoelectric converter 431 of the first PIC chip 401 and the distance between the second optical fiber 522 and the second photoelectric converter 432 of the second PIC chip 402a may be adjusted by moving the optical fiber unit 500 in the horizontal direction.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been particularly shown and described, it will be understood that various changes in form and details may be made therein without departing from the spirit and scope of the following claims.

What is claimed is:

1. A semiconductor package comprising:
a package substrate;
an electronic integrated circuit chip mounted on the package substrate;
a first photonic integrated circuit chip mounted on the electronic integrated circuit chip, the first photonic integrated circuit chip including a first groove defined at a top surface and a side surface of the first photonic integrated circuit chip; and
a second photonic integrated circuit chip mounted on the first photonic integrated circuit chip, the second photonic integrated circuit chip including a second groove defined at a top surface and a side surface of the second photonic integrated circuit chip,
wherein the second photonic integrated circuit chip is offset-stacked on the first photonic integrated circuit chip, such that at least a portion of a bottom surface of the first groove of the first photonic integrated circuit chip is vertically exposed outside the second photonic integrated circuit chip.

2. The semiconductor package of claim 1, wherein:
the first photonic integrated circuit chip includes a first photoelectric converter at a top of the first photonic integrated circuit chip,
the second photonic integrated circuit chip includes a second photoelectric converter at a top of the second photonic integrated circuit chip,
the first photoelectric converter includes an edge coupler at an end of the first photoelectric converter that is adjacent to the first groove of the first photonic integrated circuit chip, and
the second photoelectric converter includes an edge coupler at an end of the second photoelectric converter that is adjacent to the second groove of the second photonic integrated circuit chip.

3. The semiconductor package of claim 1, wherein:
the first groove of the first photonic integrated circuit chip is an opening at a first side surface of the first photonic integrated circuit chip, and
the second groove of the second photonic integrated circuit chip is an opening in a second side surface of the second photonic integrated circuit chip.

4. The semiconductor package of claim 3, wherein a direction in which the first side surface of the first photonic integrated circuit chip faces is a same as a direction in which the second side surface of the second photonic integrated circuit chip faces.

5. The semiconductor package of claim 4, wherein the second side surface of the second photonic integrated circuit chip is located above the top surface of the first photonic integrated circuit chip.

6. The semiconductor package of claim 5, wherein:
a third side surface of the first photonic integrated circuit chip that is adjacent to the first side surface of the first photonic integrated circuit chip is coplanar with a fourth side surface of the second photonic integrated circuit chip that is adjacent to the second side surface of the second photonic integrated circuit chip, and
a distance between the first groove of the first photonic integrated circuit chip and the third side surface of the first photonic integrated circuit chip is equal to a distance between the second groove of the second photonic integrated circuit chip and the fourth side surface of the second photonic integrated circuit chip.

7. The semiconductor package of claim 5, wherein:
a third side surface of the first photonic integrated circuit chip that is adjacent to the first side surface of the first photonic integrated circuit chip is coplanar with a fourth side surface of the second photonic integrated circuit chip that is adjacent to the second side surface of the second photonic integrated circuit chip, and
a distance between the first groove of the first photonic integrated circuit chip and the third side surface of the first photonic integrated circuit chip is different from a distance between the second groove of the second photonic integrated circuit chip and the fourth side surface of the second photonic integrated circuit chip.

8. The semiconductor package of claim 3, wherein a side surface of the second photonic integrated circuit chip that is adjacent to the second side surface of the second photonic integrated circuit chip is located above the top surface of the first photonic integrated circuit chip.

9. The semiconductor package of claim 1, wherein:
the second photonic integrated circuit chip includes a third groove defined at a bottom surface and the side surface of the second photonic integrated circuit chip, and
the third groove of the second photonic integrated circuit chip is located above the first groove of the first photonic integrated circuit chip.

10. The semiconductor package of claim 1, further comprising a semiconductor chip mounted on the package substrate,
wherein the semiconductor chip is spaced apart from the electronic integrated circuit chip in a horizontal direction.

11. A semiconductor package comprising:
a package substrate;
an electronic integrated circuit chip mounted on the package substrate;
a first photonic integrated circuit chip mounted on the electronic integrated circuit chip, the first photonic integrated circuit chip including a first groove defined at a top surface and a side surface of the first photonic integrated circuit chip;
a second photonic integrated circuit chip mounted on the first photonic integrated circuit chip, the second photonic integrated circuit chip including a second groove defined at a top surface and a side surface of the second photonic integrated circuit chip; and
an optical fiber unit including a frame, a first optical fiber, and a second optical fiber spaced apart from the first optical fiber in a vertical direction,
wherein the first optical fiber extends from the frame of the optical fiber unit into the first groove of the first photonic integrated circuit chip,
wherein the second optical fiber extends from the frame of the optical fiber unit into the second groove of the second photonic integrated circuit chip, and
wherein the second photonic integrated circuit chip is offset-stacked on the first photonic integrated circuit chip, such that at least a portion of a bottom surface of the first groove of the first photonic integrated circuit chip is vertically exposed outside the second photonic integrated circuit chip.

12. The semiconductor package of claim 11, wherein:
the first groove of the first photonic integrated circuit chip extends inward from a first side surface of the first photonic integrated circuit chip,
the second groove of the second photonic integrated circuit chip extends inward from a second side surface of the second photonic integrated circuit chip, and
the first side surface of the first photonic integrated circuit chip and the second side surface of the second photonic integrated circuit chip face the frame of the optical fiber unit.

13. The semiconductor package of claim 12, wherein the first side surface of the first photonic integrated circuit chip is closer to the frame of the optical fiber unit than is the second side surface of the second photonic integrated circuit chip.

14. The semiconductor package of claim 12, wherein an extension length of the first optical fiber is less than an extension length of the second optical fiber.

15. The semiconductor package of claim 14, wherein a difference between the extension length of the first optical fiber and the extension length of the second optical fiber is greater than a difference between a distance between the second photonic integrated circuit chip and the frame and a distance between the first photonic integrated circuit chip and the frame.

16. The semiconductor package of claim 11, wherein:
the first photonic integrated circuit chip is spaced apart from the frame of the optical fiber unit in a first horizontal direction, and
the second photonic integrated circuit chip is stacked on the first photonic integrated circuit chip with an offset in a second horizontal direction that is perpendicular to the first horizontal direction.

17. The semiconductor package of claim 11, wherein:
the package substrate includes an alignment hole extending inward from a side surface of the package substrate,
the optical fiber unit further includes an alignment pin extending from the frame into the alignment hole of the package substrate, and
a length of the alignment hole is greater than an extension length of the first optical fiber.

18. A semiconductor package comprising:
a main package substrate;
a semiconductor chip mounted on a central portion of the main package substrate;
a sub package substrate mounted on an edge portion of the main package substrate and spaced apart from the semiconductor chip in a horizontal direction;
an electronic integrated circuit chip mounted on the sub package substrate;
a first photonic integrated circuit chip mounted on the electronic integrated circuit chip, the first photonic integrated circuit chip including a first photoelectric converter and a first groove defined at a top surface and a first side surface of the first photonic integrated circuit chip; and
a second photonic integrated circuit chip mounted on the first photonic integrated circuit chip, the second photonic integrated circuit chip including a second photoelectric converter and a second groove defined at a top surface and a second side surface of the second photonic integrated circuit chip,
wherein the first photoelectric converter includes an edge coupler at an end of the first photoelectric converter that is adjacent to the first groove of the first photonic integrated circuit chip,
the second photoelectric converter includes an edge coupler at an end of the second photoelectric converter that is adjacent to the second groove of the second photonic integrated circuit chip, and
the second photonic integrated circuit chip is offset-stacked on the first photonic integrated circuit chip, such that at least a portion of an upper surface of the first groove of the first photonic integrated circuit chip is vertically exposed outside the second photonic integrated circuit chip.

19. The semiconductor package of claim 18, wherein:
a direction in which the first side surface of the first photonic integrated circuit chip faces is a same as a direction in which the second side surface of the second photonic integrated circuit chip faces, and
the second side surface of the second photonic integrated circuit chip is located above the top surface of the first photonic integrated circuit chip.

20. The semiconductor package of claim 18, wherein:
the second photonic integrated circuit chip includes a third groove defined at a bottom surface and the second side surface of the second photonic integrated circuit chip, and
the third groove of the second photonic integrated circuit chip is located above the first groove of the first photonic integrated circuit chip.
